(19) United States
(12) Patent Application Publication
(10) Pub. No.: US 2023/0387074 A1
(43) Pub. Date: Nov. 30, 2023

(54) INTEGRATED CIRCUIT ASSEMBLIES HAVING INTERCONNECTION BRIDGES SPANNING RETICLE BOUNDARY / DICING STREETS OF MONOLITHIC STRUCTURES THEREIN

(71) Applicant: Intel Corporation, Santa Clara, CA (US)

(72) Inventors: Debendra Mallik, Chandler, AZ (US); Nitin Deshpande, Chandler, AZ (US); Satish Damaraju, El Dorado Hills, CA (US); Scott Siers, Elk Grove, CA (US); Kai-Chiang Wu, Hsinchu City (TW)

(73) Assignee: Intel Corporation, Santa Clara, CA (US)

(21) Appl. No.: 17/825,350

(22) Filed: May 26, 2022

(51) Int. Cl. H01L 25/065; H01L 23/498; H01L 23/31; H01L 23/538; H01L 23/00

(52) U.S. Cl. CPC H01L 25/0652; H01L 23/49816; H01L 23/3128; H01L 23/5385; H01L 24/16; H01L 2224/16146; H01L 2224/16227; H01L 2225/06513

(57) ABSTRACT

An integrated circuit assembly may be formed having a first level structure that comprises a monolithic substrate with a first reticle zone including integrated circuitry and a second reticle zone including integrated circuitry, and a second level structure comprising at least one integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

### TECHNICAL FIELD

Embodiments of the present description generally relate to the field of integrated circuit package fabrication, and, more specifically, to an integrated circuit assembly including an integrated circuit stack having a first level structure and a second level structure, wherein the first level structure includes a monolithic substrate having at least two reticle zones, and wherein the second level structure has a bridge providing electrical signal connection between the at least two reticle zones.

### BACKGROUND

The integrated circuit industry is continually striving to produce ever faster, smaller, and thinner integrated circuit packages for use in various electronic products, including, but not limited to, computer servers and portable products, such as portable computers, electronic tablets, cellular phones, digital cameras, and the like.

As a part of this effort, integrated circuit packages containing stacked integrated circuit devices have been developed and offer the potential for increased architectural flexibility at reduced cost, but must do so such that appropriate integrated circuit device-to-integrated circuit device interconnect densities are provided. As will be understood to those skilled in the art, interconnect density is an important consideration because an insufficient number of integrated circuit device connections would limit the bandwidth capability for the affected integrated circuit device interface, and thus would reduce the communication efficiency and capability between integrated circuit devices. The integrated circuit devices in an individual stack may be interconnected with high-density interconnection bonds, as known in the art, wherein the high-density interconnection bonds have a pitch of about 9 microns or less. As will be understood to those skilled in the art, these high-density interconnection bonds are limited to individual integrated circuit device stacks and, thus, limited to the size of the largest die in the die stack, which is determined by the maximum size of a lithographic reticle or less, e.g., about 26 mm by 33 mm or less. However, there is a need to form high-speed connections between the individual device stacks.

One method to form these high-speed connections is with a bridge that is embedded in a substrate to which the stacked integrated circuit devices are attached. These bridges support dense integrated circuit device-to-integrated circuit device interconnects, such as between individual integrated circuit device stacks, and may support a number of signal lines through the bridge itself. Instead of using an expensive silicon interposer with through silicon vias, the bridge may be an inactive silicon structure or an active silicon device that is embedded in the substrate, enabling the dense integrated circuit device-to-integrated circuit device interconnects only where needed. However, such bridges create relatively long interconnections distances and increases the cost of the integrated circuit packages. Moreover, the bandwidth of the bridge is limited by the bump pitch between the integrated circuit stacks and the substrate (e.g., between about 30 microns and 50 microns), which is 10 to 25 times less area efficient compared to the pitch of high-density interconnection bonds (e.g., about 9 microns or less) between the integrated circuits devices in the individual integrated circuit stacks, as will be understood to those skilled in the art.

Another method to form the high-speed connections is by reticle stitching. Reticle stitching involves forming at least one high-density wiring layer across reticle boundaries/dicing zones between the individual integrated circuit device stacks in the metallization layers that interconnect the integrated circuit devices in each of the individual integrated circuit device stacks, as will be understood to those skilled in the art. However, forming such reticle stitching may require additional fabrication processes that may be prohibitively expensive.

Thus, there is a need to develop packaging strategies and devices to increase interconnect densities and bandwidth between individual integrated circuit device stacks.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit package, according to one embodiment of the present description.

FIGS. 2-4 are top plane views of a various configurations for the integrated circuit package of FIG. 1, according to an embodiment of the present description.

FIGS. 5-9 are side cross-sectional views of various integrated circuit packages, according to embodiments of the present description.

FIG. 10 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description relate to forming stacked integrated circuit packages, wherein the stacked integrated circuit package includes a first level structure that comprises a monolithic substrate having a first reticle zone including integrated circuitry and a second reticle zone including integrated circuitry, and a second level structure comprising at least one integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

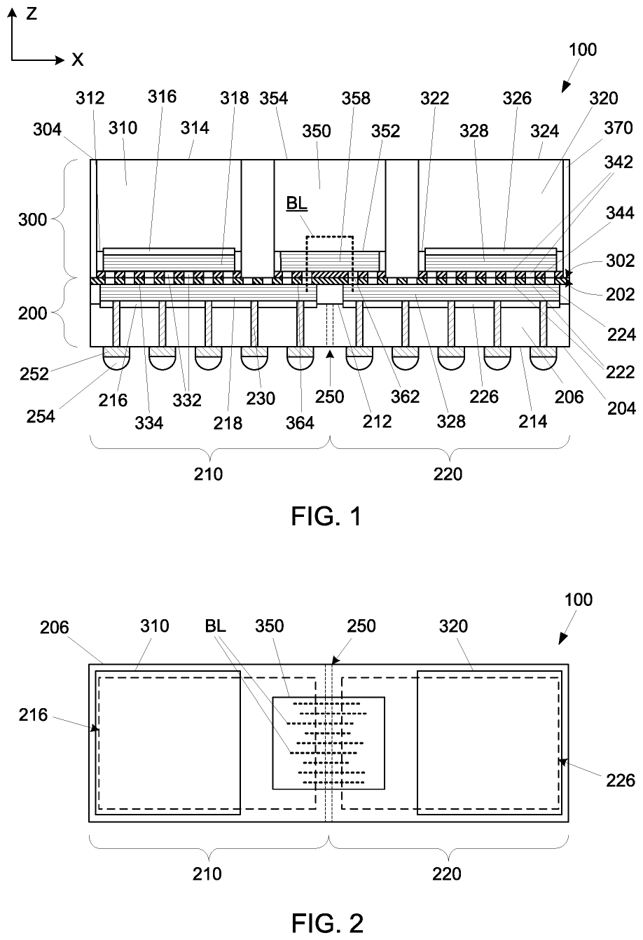

As shown in FIG. 1, an integrated circuit package 100 may be formed with a first level structure 200 and a second level structure 300 electrically attached to the first level structure 200. In one embodiment, the first level structure 200 may have a frontside surface 202 and an opposing backside surface 204 and may include a monolithic substrate 206 having a first surface 212 and an opposing backside surface 214. The term “monolithic substrate” for the purposes of the present description is defined to mean a structure formed from and/or being a single material structure.

As illustrated, the backside surface 214 of the monolithic substrate 206 may also be at least a portion of the backside surface 204 of the first level structure 200. The monolithic substrate 206 may have a plurality of reticle zones (shown as a first reticle zone 210 and a second reticle zone 220) formed thereon. As shown in FIG. 1, integrated circuitry 216 may be formed in or on the frontside surface 212 of the monolithic substrate 206 within the first reticle zone 210, and integrated circuitry 226 may be formed in or on the frontside surface 212 of the monolithic substrate 206 within the second reticle zone 220. As will be understood to those skilled in the art, the monolithic substrate 206 may be a portion of a semiconductor wafer, such as a silicon wafer. In an embodiment of the present description, the monolithic substrate 206 may include a boundary zone 250 (demarked by parallel dashed lines) between the first reticle zone 210 and the second reticle zone 220. The boundary zone 250 may be an area wherein the monolithic substrate 206 would ordinarily be diced or cut into individual reticle zones with a wafer saw to form singulated dice. Thus, the boundary zone 250 may include guard rings, dicing structures, and the like, as will be understood to those skilled in the art.

The integrated circuitry 216 of the first reticle zone 210 and the integrated circuitry 226 of the second reticle zone 220 may be any appropriate integrated circuit device, including, but not limited to, a microprocessor, a chipset, a graphics device, a wireless device, a memory device, an application specific integrated circuit device, combinations thereof, and the like.

As shown in FIG. 1, a routing layer 218 may be formed on the integrated circuitry 216 of the first reticle zone 210 of the monolithic substrate 206 and a second routing layer 228 formed on the integrated circuitry 226 of the second reticle zone 220 of the monolithic substrate 206. As will be understood to those skilled in the art, routing layers, such as the routing layers 218 and 228, are used to route signals and power to and from the integrated circuitry 216 and 226, respectively. The routing layers 218 and 228 may comprise alternating layers of dielectric material (not labeled) and conductive routes (not shown). The dielectric material layers (not labeled) may include, silicon oxide, silicon nitride, carbon doped dielectrics, fluorine doped dielectrics, porous dielectrics, organic polymeric dielectrics, and the like. The conductive routes (not shown) may be a combination of conductive traces (not shown) and conductive vias (not shown) extending through the plurality of dielectric material layers (not labeled). These conductive traces and conductive vias are well known in the art and are not shown in FIG. 1 for purposes of clarity and conciseness. The conductive traces and the conductive vias may be made of any appropriate conductive material, including but not limited to, metals, such as copper, silver, nickel, gold, and aluminum, alloys thereof, and the like.

A plurality of high-density interconnects 222 may be formed over the routing layers 218 and 228. For the purposes of the present description, the high-density interconnects will be defined to mean interconnect which have a pitch of about 9 microns or less. As further shown in FIG. 1, a dielectric material 224 may be disposed adjacent to the high-density interconnects 222 for electrical isolation therebetween.

As further shown in FIG. 1, a plurality of bond pads 252 may be formed on the backside surface 204 for the first level structure 200. These bond pads 252 may be electrically attached to the routing layers 218 and 228 to the backside surface 204 of the first level structure 200 through a plurality of through-silicon vias 230 extending at least partially through the first level structure 200. A plurality of external interconnects 254 may be formed on the plurality of bond pads 252. The external interconnects 254 may be any appropriate electrically conductive material or structure, including but not limited to, solder balls, metal bumps or pillars, metal filled epoxies, or a combination thereof. In one embodiment, the external interconnects 254 may be solder balls formed from tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). In another embodiment, the external interconnects 254 may be copper bumps or pillars. In a further embodiment, the external interconnects 254 may be metal bumps or pillars coated with a solder material.

In one embodiment, the second level structure 300 may have a frontside surface 302 and an opposing backside surface 304 and may include at least one integrated circuit device, such as a first integrated circuit device 310 and a second integrated circuit device 320, as shown in FIG. 1. The first integrated circuit device 310 and the second integrated circuit device 320 may be any appropriate integrated circuit device, including, but not limited to, a microprocessor, a chipset, a graphics device, a wireless device, a memory device, an application specific integrated circuit device, combinations thereof, and the like. The first integrated circuit device 310 may have a frontside surface 312 and an opposing backside surface 314, and integrated circuitry 316 formed in or on the frontside surface 312 thereof. The second integrated circuit device 320 may have a frontside surface 322 and an opposing backside surface 324, and integrated circuitry 326 formed in or on the frontside surface 322 thereof.

As shown in FIG. 1, a routing layer 318 may be formed on the integrated circuitry 316 of the first integrated circuit device 310 and a routing layer 328 formed on the integrated circuitry 326 of the second integrated circuit device 320. As previously discussed, routing layers, such as the routing layer 318 and 328, are used to route signals and power to and from the integrated circuit devices 310 and 320, respectively. The routing layers 318 and 328 may comprise alternating layers of dielectric material (not labeled) and conductive routes (not shown). The dielectric material layers (not labeled) may include, silicon oxide, silicon nitride, carbon doped dielectrics, fluorine doped dielectrics, porous dielectrics, organic polymeric dielectrics, and the like. The conductive routes (not shown) may be a combination of conductive traces (not shown) and conductive vias (not shown) extending through the plurality of dielectric material layers (not labeled). Again, these conductive traces and conductive vias are well known in the art and are not shown for purposes of clarity and conciseness. The conductive traces and the conductive vias may be made of any appropriate conductive material, including but not limited to, metals, such as copper, silver, nickel, gold, and aluminum, alloys thereof, and the like.

A plurality of high-density interconnects 332 may be formed on the routing layer 318 of the first integrated circuit device 310 and a plurality of high-density interconnects 342 maybe formed on the routing layer 328 of the second integrated circuit device 320. As further shown in FIG. 1, a dielectric material 334 may be disposed adjacent to the high-density interconnects 332 of the first integrated circuit device 310 for electrical isolation therebetween, and a dielectric material 344 may be disposed adjacent to the high-density interconnects 342 of the second integrated circuit device 320 for electrical isolation therebetween.

As further shown in FIG. 1, the second level structure 300 may further include a bridge 350. The bridge 350 may have a frontside surface 352, an opposing backside surface 354, and a routing layer 358 formed on the frontside surface 352 of the bridge 350. The routing layer 358 may be formed in a manner and with materials as discussed with regard to routing layers 318 and 328. A plurality of high-density interconnects 362 may be formed on the routing layer 358 of the bridge 350. As further shown, a dielectric material 364 may be disposed adjacent to the high-density interconnects 362 of the bridge 350 for electrical isolation therebetween. In one embodiment of the present description, the bridge 350 may be passive, e.g., containing no transistors, and may contain capacitors, resistors, swizzling of wiring, and/or the like.

The plurality of high-density interconnects 332 of the first integrated circuit device 310, the plurality of high-density interconnects 342 of the second integrated circuit device 320, and the plurality of high-density interconnects 362 of the bridge 350 may be electrically attached to the corresponding high-density interconnects 222 of the first level structure 200 by any technique known in the art, including, but not limited to a hybrid bonding technique. The hybrid bonding technique is a fusion bonding method by plasma treating of the surfaces, room temperature contact of the surfaces to form a bond therebetween, and followed thermal annealing to strengthen the bond.

A mold material 370 may be disposed adjacent the first integrated circuit device 310, the second integrated circuit device 320, and the bridge 350. The mold material 370 may be any appropriate encapsulation material, including, but not limited to, epoxy materials, or may be any appropriate dielectric material, including, but not limited to, silicon oxide, silicon nitride, carbon doped dielectrics, fluorine doped dielectrics, porous dielectrics, organic polymeric dielectrics, and the like. In one embodiment, the backside surface 314 of the first integrated circuit device 310, the backside surface 324 of the second integrated circuit device 320, the backside surface 354 of the bridge 350, and the mold material 370 may form the backside surface 304 of the second level structure 300. In another embodiment, the backside surface 314 of the first integrated circuit device 310, the backside surface 324 of the second integrated circuit device 320, and/or the backside surface 354 of the bridge 350 may be on substantially the same plane with one another.

The bridge 350 may be positioned to straddle the boundary zone 250 of the first level structure 200 such that it may make an electrical connection between the first reticle zone 210 and the second reticle zone 220. This electrical connection is illustrated as a dashed line and labeled as a bridge line BL. The straddling of the boundary zone 250 may be more clearly seen in FIG. 2, which is a top plan view of FIG. 1, wherein some components are not illustrated to more clearly and concisely show the relation between the bridge 350 and the boundary zone 250 between the first reticle zone 210 and the second reticle zone 220. In one embodiment of the present description, the bridge 350 may be positioned to vertically (i.e., z-direction) overlap a portion of the first reticle zone 210 and a portion of the second reticle zone 220 to minimize length of the bridge lines BL.

In one embodiment, the bridge 350 may comprise silicon-containing components. As will be understood to those skilled in the art, silicon bridges may be preferred because silicon processing technology is relatively advanced, and interconnect pitches and line widths for the bridge line BL that are achievable using existing silicon process technology may be significantly smaller, and thus, denser than what is possible using, for example, currently available technology for copper signal lines in polymer layers, as is common in electronic substrate fabrication.

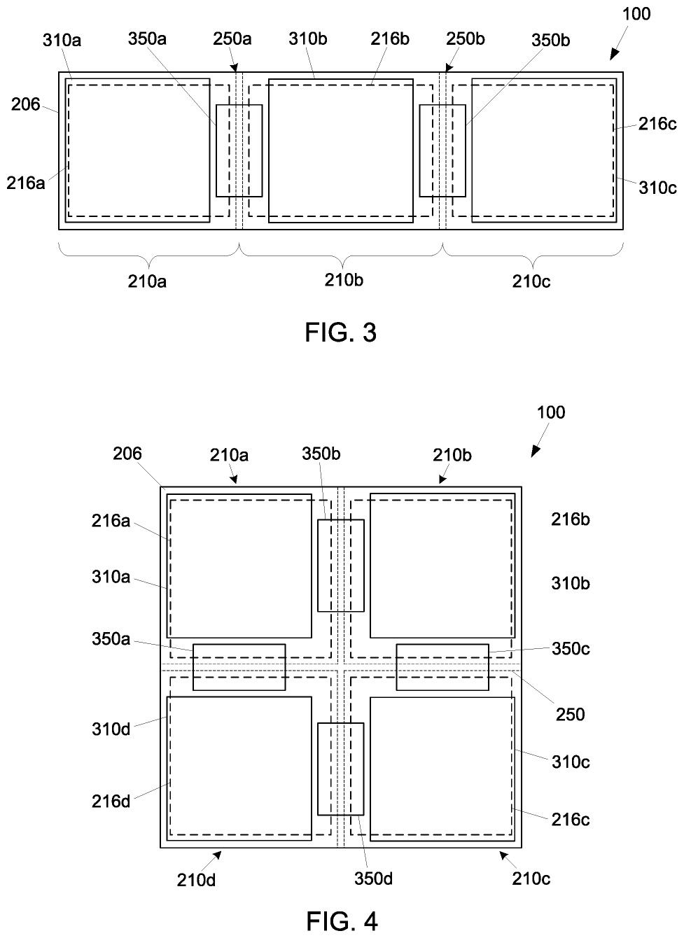

Although the embodiments of FIGS. 1 and 2 illustrates a single bridge 350 electrically attaching two reticle zones, e.g., the first reticle zone 210 and the second reticle zone 220, the embodiments of the present description are not so limited, as any appropriate number of reticle zones and bridges may be utilized. By way of example, as shown in FIG. 3, three reticle zones may be attached with two bridges (top plan view). More specifically, a first bridge 350a may straddle a first boundary 250a between and electrically attaching reticle zone 210a and reticle zone 210b, and a second bridge 350b may straddle a second boundary 250b between and electrically attaching reticle zone 201b and reticle zone 210c. By way of another example, as shown in FIG. 4, multiple bridges may straddle a boundary and electrically attach multiple reticle zones. More specifically, the first bridge 350a may straddle a boundary 250 (single attached zone separating all reticle zones) between and electrically attaching reticle zone 210a and reticle zone 210d, the second bridge 350b may straddle the boundary 250 between and electrically attaching reticle zone 210a and reticle zone 210b, the third bridge 350c may straddle the boundary 250 between and electrically attaching reticle zone 210b and reticle zone 210c, and a fourth bridge 350d may straddle the boundary 250 between and electrically attaching reticle zone 210c and reticle zone 210d.

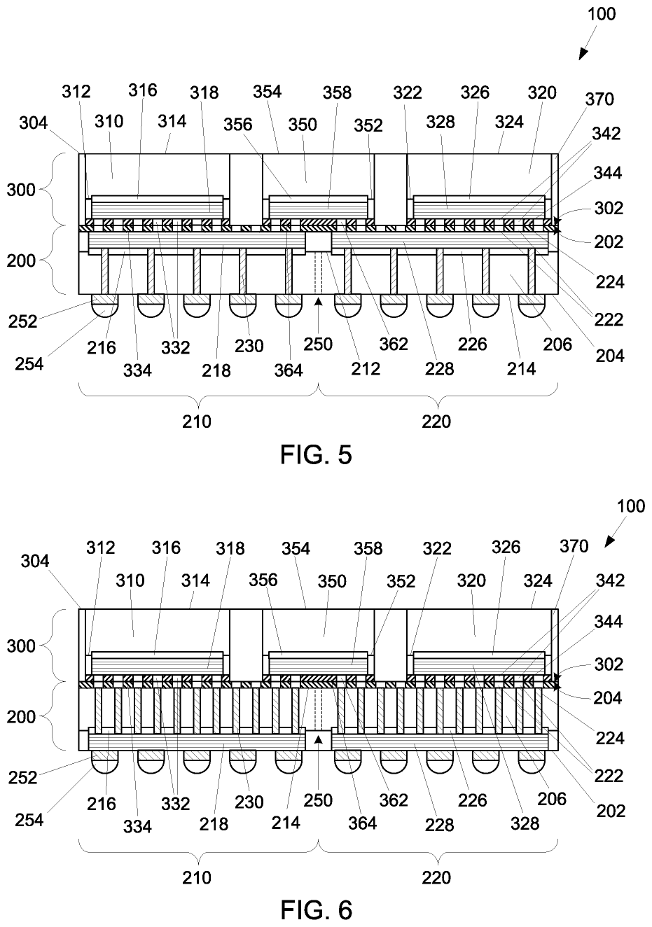

In an embodiment of the present description, the bridge 350 may be active, as shown in FIG. 5. In other words, the bridge 350 may include an integrated circuit layer 356 formed in or on the frontside surface 352 thereof. In one embodiment, integrated circuit layer 356 may include at least one repeater to manage interconnect length, or may include circuitry for functions, including, but not limited to, fusing, sku management, and the like.

Although the embodiment of FIG. 1 shows a “face-to-face” configuration, wherein the frontside surface 212 of the monolithic substrate 206 faces the frontside surfaces 312 and 322 of the integrated circuit devices 310 and 320, respectively, and the frontside surface 352 of the bridge 350 of the second level structure 300, the embodiments of the present description are not so limited. As shown in FIG. 6, the integrated circuit package 100 may be configured in a “face-to-back” configuration, wherein the frontside surfaces 312 and 322 of the integrated circuit devices 310 and 320, respectively, and the frontside surface 352 of the bridge 350 of the second level structure 300 face the backside surface 214 of the monolithic substrate 206. As shown the through-silicon vias 230 make electrical contact with the high-density interconnects 222, and the routing layers 218 and 228 of the first reticle zone 216 and the second reticle zone 226, respectively, make electrical contact with corresponding bond pads 252.

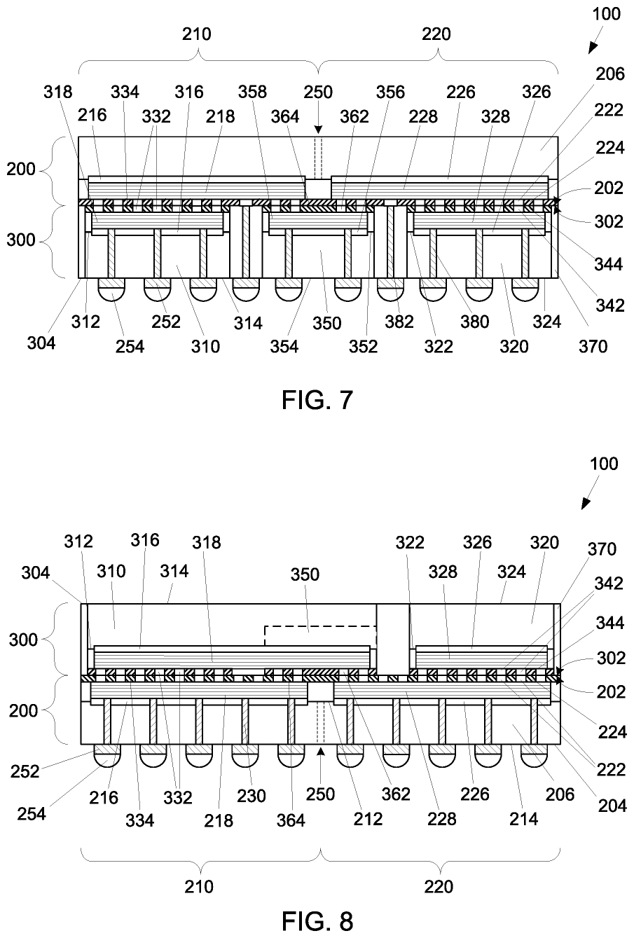

As shown in FIG. 7, in one embodiment of the present description, the embodiment of FIG. 5 may be flipped, such that second level structure 300 has the bond pads 252 and the external interconnects 254 on the backside surface 304 thereof. In this embodiment, the through-silicon vias 230 may be formed through the first integrated circuit device 310 to electrically attach a portion of the bond pads 252 to the routing layer 318 thereof and formed through the second integrated circuit device 310 to electrically attach another portion of the bond pads 252 to the routing layer 328 thereof. Furthermore, at least one through-mold via 382 may extend through the mold material 370 to electrically attached at least one bond pad 252 to at least one high density interconnect 222 of the first level structure 200.

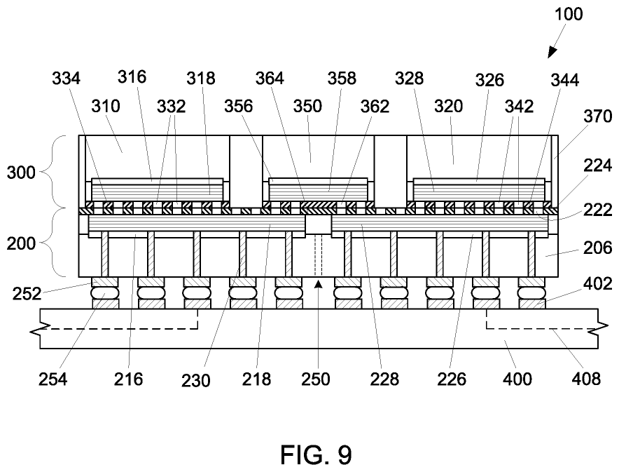

Although the embodiments of FIGS. 1-8 illustrate the bridge 350 as a separate structure from the integrated circuit devices of the second level structure 300, the embodiments of the present description are not so limited. As shown in FIG. 9, the bridge 350 may be formed as part of an integrated circuit device, e.g., first integrated circuit device 310, and the portion of the integrated circuit device 310 having the bridge 350 may straddle the boundary 250 between the first reticle zone 210 and the second reticle zone 220 and form an electrical attachment therebetween as previously discussed.

In additional embodiments of the present description, any of the integrated circuit packages 100 of this application may be electrically attached to a carrier substrate 400. By way of example, FIG. 9 illustrates the integrated circuit package 100 of FIG. 1 attached to the carrier substrate 400, wherein the external interconnects 254 of the integrated circuit package 100 may be electrically attached to bond pads 402 on or in the carrier substrate 400.

The carrier substrate 400 may be any appropriate structure, including, but not limited to, an interposer, motherboard, or the like. The carrier substrate 400 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide materials, silica filled epoxy, glass reinforced epoxy material, and the like, as well as low-k and ultra low-k dielectrics (dielectric constants less than about 3.6), including but not limited to carbon doped dielectrics, fluorine doped dielectrics, porous dielectrics, organic polymeric dielectrics, and the like.

The carrier substrate 400 may further include conductive routes 408 or “metallization” (shown in dashed lines) extending through the carrier substrate 400. As will be understood to those skilled in the art, the conductive routes 408 may be a combination of conductive traces (not shown) and conductive vias (not shown) extending through the plurality of dielectric material layers (not shown). These conductive traces and conductive vias are well known in the art and are not shown in FIG. 9 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the carrier substrate 400 may be a cored or coreless substrate. At least one of the conductive routes 408 may be attached to at least one of the bond pads 402 of the carrier substrate for attachment to external components (not shown), such as to other integrated circuit packages or devices (not shown) that are also electrically attached to the carrier substrate 400.

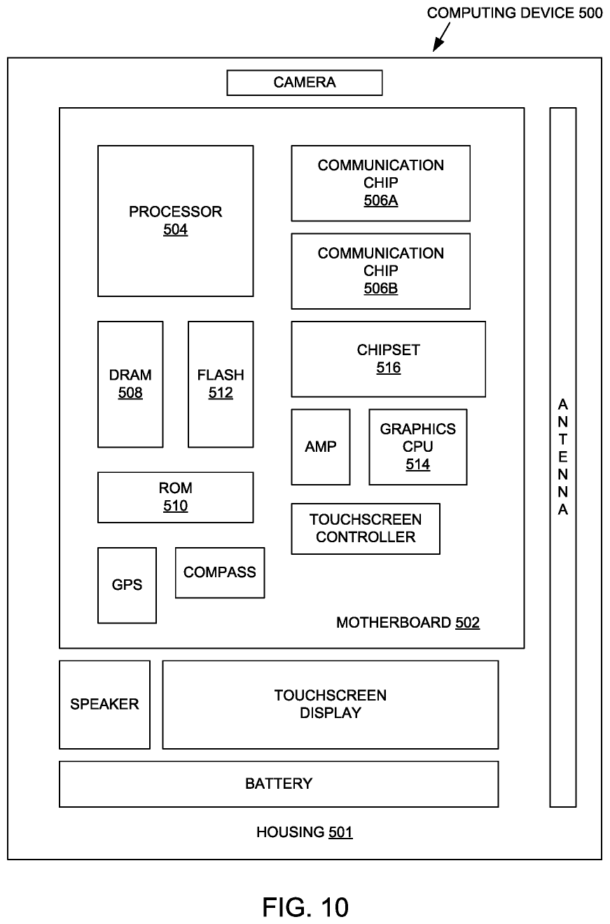

FIG. 10 illustrates an electronic or computing device 500 in accordance with one implementation of the present description. The computing device 500 may include a housing 501 having a board 502 disposed therein. The computing device 500 may include a number of integrated circuit components, including but not limited to a processor 504, at least one communication chip 506A, 506B, volatile memory 508 (e.g., DRAM), non-volatile memory 510 (e.g., ROM), flash memory 512, a graphics processor or CPU 514, a digital signal processor (not shown), a crypto processor (not shown), a chipset 516, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 502. In some implementations, at least one of the integrated circuit components may be a part of the processor 504.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an integrated circuit package comprising a first level structure, wherein the first level structure comprises a monolithic substrate having a first reticle zone including integrated circuitry and a second reticle zone including integrated circuitry, and a second level structure, wherein the second level structure comprises an integrated circuit device electrically attached to the integrated circuitry of the first reticle zone of the first level structure and a bridge electrically connecting the integrated circuitry of the first reticle zone of the first level structure and the integrated circuitry of the second reticle zone of the first level structure.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-10. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an apparatus comprising a first level structure, wherein the first level structure comprises a monolithic substrate having a first reticle zone including integrated circuitry, and a second reticle zone including integrated circuitry; and a second level structure, wherein the second level structure comprises an integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

In Example 2, the subject matter of Example 1 can optionally include the first level structure further including a boundary zone between the first reticle zone and the second reticle zone and wherein the bridge is positioned over the boundary zone.

In Example 3, the subject matter of any of Examples 1 to 2 can optionally include the bridge comprising a portion of the integrated circuit device.

In Example 4, the subject matter of any of Examples 1 to 3 can optionally include the bridge comprising a passive device.

In Example 5, the subject matter of any of Examples 1 to 3 can optionally include the bridge comprising an active device.

In Example 6, the subject matter of any of Examples 1 to 5 can optionally include a backside surface of the integrated circuit device being planar with a backside surface of the bridge.

In Example 7, the subject matter of any of Examples 1 to 6 can optionally include a second integrated device electrically attached to the integrated circuitry of the second reticle zone of the first level structure.

In Example 8, the subject matter of any of Examples 1 to 7 can optionally include a plurality of external interconnects attached to the first level structure.

In Example 9, the subject matter of Example 8 can optionally include the external interconnects are electrically attached to the integrated circuitry of the first reticle zone and the integrated circuitry of the second reticle zone with a plurality of through-silicon vias extending through the monolithic substrate.

In Example 10, the subject matter of any of Examples 1 to 7 can optionally include a plurality of external interconnects attached to the second level structure.

In Example 11, the subject matter of Example 10 can optionally include the external interconnects being electrically attached to the integrated circuit device with a plurality of through-silicon vias extending through the integrated circuit device.

In Example 12, the subject matter of Example 10 can optionally include a mold material abutting the integrated circuit device and the bridge.

In Example 13, the subject matter of Example 12 can optionally include a through-mold via extending thought the mold material and electrically attaching the external interconnects to the first level structure.

Example 14 is an apparatus comprising a carrier substrate and an integrated circuit package electrically attached to the carrier substrate, wherein the integrated circuit package comprises a first level structure, wherein the first level structure comprises a monolithic substrate having a first reticle zone including integrated circuitry, and a second reticle zone including integrated circuitry; and a second level structure, wherein the second level structure comprises an integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

In Example 15, the subject matter of Example 14 can optionally include the first level structure further including a boundary zone between the first reticle zone and the second reticle zone and wherein the bridge is positioned over the boundary zone.

In Example 16, the subject matter of any of Examples 14 to 15 can optionally include the bridge comprising a portion of the integrated circuit device.

In Example 17, the subject matter of any of Examples 14 to 16 can optionally include the bridge comprising a passive device.

In Example 18, the subject matter of any of Examples 14 to 16 can optionally include the bridge comprising an active device.

In Example 19, the subject matter of any of Examples 14 to 18 can optionally include a backside surface of the integrated circuit device being planar with a backside surface of the bridge.

In Example 20, the subject matter of any of Examples 14 to 19 can optionally include a second integrated device electrically attached to the integrated circuitry of the second reticle zone of the first level structure.

In Example 21, the subject matter of any of Examples 14 to 20 can optionally include a plurality of external interconnects attached to the first level structure.

In Example 22, the subject matter of Example 21 can optionally include the external interconnects are electrically attached to the integrated circuitry of the first reticle zone and the integrated circuitry of the second reticle zone with a plurality of through-silicon vias extending through the monolithic substrate.

In Example 23, the subject matter of any of Examples 14 to 20 can optionally include a plurality of external interconnects attached to the second level structure.

In Example 24, the subject matter of Example 23 can optionally include the external interconnects being electrically attached to the integrated circuit device with a plurality of through-silicon vias extending through the integrated circuit device.

In Example 25, the subject matter of Example 23 can optionally include a mold material abutting the integrated circuit device and the bridge.

In Example 26, the subject matter of Example 25 can optionally include a through-mold via extending thought the mold material and electrically attaching the external interconnects to the first level structure.

Example 27 is an electronic system apparatus comprising a board; a carrier substrate, wherein the carrier substrate is electrically attached to the board; and an integrated circuit package electrically attached to the carrier substrate, wherein the integrated circuit package comprises a first level structure, wherein the first level structure comprises a monolithic substrate having a first reticle zone including integrated circuitry, and a second reticle zone including integrated circuitry; and a second level structure, wherein the second level structure comprises an integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

In Example 28, the subject matter of Example 1 can optionally include the first level structure further including a boundary zone between the first reticle zone and the second reticle zone and wherein the bridge is positioned over the boundary zone.

In Example 29, the subject matter of any of Examples 1 to 2 can optionally include the bridge comprising a portion of the integrated circuit device.

In Example 30, the subject matter of any of Examples 1 to 3 can optionally include the bridge comprising a passive device.

In Example 31, the subject matter of any of Examples 1 to 3 can optionally include the bridge comprising an active device.

In Example 32, the subject matter of any of Examples 1 to 5 can optionally include a backside surface of the integrated circuit device being planar with a backside surface of the bridge.

In Example 33, the subject matter of any of Examples 1 to 6 can optionally include a second integrated device electrically attached to the integrated circuitry of the second reticle zone of the first level structure.

In Example 34, the subject matter of any of Examples 1 to 7 can optionally include a plurality of external interconnects attached to the first level structure.

In Example 35, the subject matter of Example 8 can optionally include the external interconnects are electrically attached to the integrated circuitry of the first reticle zone and the integrated circuitry of the second reticle zone with a plurality of through-silicon vias extending through the monolithic substrate.

In Example 36, the subject matter of any of Examples 1 to 7 can optionally include a plurality of external interconnects attached to the second level structure.

In Example 37, the subject matter of Example 10 can optionally include the external interconnects being electrically attached to the integrated circuit device with a plurality of through-silicon vias extending through the integrated circuit device.

In Example 38, the subject matter of Example 10 can optionally include a mold material abutting the integrated circuit device and the bridge.

In Example 39, the subject matter of Example 5 can optionally include a through-mold via extending thought the mold material and electrically attaching the external interconnects to the first level structure.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus comprising:
a first level structure, wherein the first level structure comprises a monolithic substrate having a first reticle zone including integrated circuitry, and a second reticle zone including integrated circuitry; and
a second level structure, wherein the second level structure comprises an integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

2. The apparatus of claim 1, wherein the first level structure further includes a boundary zone between the first reticle zone and the second reticle zone and wherein the bridge is positioned over the boundary zone.

3. The apparatus of claim 1, wherein the bridge comprises a portion of the integrated circuit device.

4. The apparatus of claim 1, wherein the bridge comprises a passive device.

5. The apparatus of claim 1, wherein the bridge comprises an active device.

6. The apparatus of claim 1, wherein a backside surface of the integrated circuit device is planar with a backside surface of the bridge.

7. The apparatus of claim 1, further including a second integrated device electrically attached to the integrated circuitry of the second reticle zone of the first level structure.

8. The apparatus of claim 1, further comprising a plurality of external interconnects attached to the first level structure.

9. The apparatus of claim 8, wherein the external interconnects are electrically attached to the integrated circuitry of the first reticle zone and the integrated circuitry of the second reticle zone with a plurality of through-silicon vias extending through the monolithic substrate.

10. The apparatus of claim 1, further comprising a plurality of external interconnects attached to the second level structure.

11. The apparatus of claim 10, wherein the external interconnects are electrically attached to the integrated circuit device with a plurality of through-silicon vias extending through the integrated circuit device.

12. The apparatus of claim 10, further comprising a mold material abutting the integrated circuit device and the bridge.

13. The apparatus of claim 12, further comprising a through-mold via extending thought the mold material and electrically attaching the external interconnects to the first level structure.

14. An apparatus comprising:
a carrier substrate; and
an integrated circuit package electrically attached to the carrier substrate, wherein the integrated circuit package comprises:
a first level structure, wherein the first level structure comprises a monolithic substrate having a first reticle zone including integrated circuitry, and a second reticle zone including integrated circuitry; and
a second level structure, wherein the second level structure comprises an integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

15. The apparatus of claim 14, wherein the first level structure further includes a boundary zone between the first reticle zone and the second reticle zone and wherein the bridge is positioned over the boundary zone.

16. The apparatus of claim 14, wherein the bridge comprises a portion of the integrated circuit device.

17. The apparatus of claim 14, wherein a backside surface of the integrated circuit device is planar with a backside surface of the bridge.

18. The apparatus of claim 14, wherein the first level structure is electrically connected to the carrier substrate with a plurality of external interconnects.

19. The apparatus of claim 14, wherein the second level structure is electrically connected to the carrier substrate with a plurality of external interconnects.

20. An electronic system comprising:
a board;
a carrier substrate, wherein the carrier substrate is electrically attached to the board; and
an integrated circuit package electrically attached to the carrier substrate, wherein the integrated circuit package comprises:
a first level structure, wherein the first level structure comprises a monolithic substrate having a first reticle zone including integrated circuitry, and a second reticle zone including integrated circuitry; and
a second level structure, wherein the second level structure comprises an integrated circuit device electrically attached to the integrated circuitry of the first reticle zone of the first level structure and a bridge electrically attaching the integrated circuitry of the first reticle zone of the first level structure and the integrated circuitry of the second reticle zone of the first level structure.

21. The electronic system of claim 20, wherein the first level structure further includes a boundary zone between the first reticle zone and the second reticle zone and wherein the bridge is positioned over the boundary zone.

22. The electronic system of claim 20, wherein the bridge comprises a portion of the integrated circuit device.

23. The electronic system of claim 20, wherein a backside surface of the integrated circuit device is planar with a backside surface of the bridge.

24. The electronic system of claim 20, wherein the first level structure is electrically connected to the carrier substrate with a plurality of external interconnects.

25. The electronic system of claim 20, wherein the second level structure is electrically connected to the carrier substrate with a plurality of external interconnects.
